(19) United States
(12) Patent Application Publication
(10) Pub. No.: US 2007/0001208 A1
(43) Pub. Date: Jan. 4, 2007

(54) DRAM having carbon stack capacitor

(76) Inventors: Andrew Graham, Muenchen (DE); Georg Duesberg, Muenchen (DE); Werner Steinhoegl, Muenchen (DE)

Correspondence Address: DICKE, BILLIG & CZAJA, P.L.L.C., FIFTH STREET TOWERS, 100 SOUTH FIFTH STREET, SUITE 2250, MINNEAPOLIS, MN, 55402, US

(21) Appl. No.: 11/170,886

(22) Filed: Jun. 30, 2005

(51) Int. Cl. H01L 27/108; H01L 21/8242

(52) U.S. Cl. 257/306; 438/253; 438/256; 438/396; 257/308

(57) ABSTRACT

A DRAM stack capacitor and a fabrication method thereof is disclosed. The DRAM stack capacitor is formed with a first capacitor electrode comprising a conductive carbon layer, a capacitor dielectric layer and a second capacitor electrode.

### FIELD OF THE INVENTION

This invention relates generally to a DRAM stack capacitor and a production method thereof.

### BACKGROUND

A semiconductor memory device like a DRAM (Dynamic Random Access Memory) is formed with a plurality of memory cells each comprising a transfer device and a storage capacitor.

A digital state within any of the memory cells, e.g., a “1” or “0” state, is correlated to an amount of charge on the storage capacitor. The transfer device is connected between the storage capacitor and a support region of the DRAM which allows access to the storage capacitor in order to charge and discharge the storage capacitor, i.e., to write and read out a logic state. The transfer device commonly constitutes an n-channel MOSFET (Metal-Oxid-Semiconductor Field Effect Transistor) having its source region connected to the storage capacitor and its drain region connected via a bitline to circuit devices (e.g., sense amplifiers) of the support region. The MOSFET transfer device allows the storage capacitor to be charged or discharged by changing its channel conductivity when applying a gate voltage via a wordline.

Known storage capacitors are either of a stack capacitor type or of a trench capacitor type. The former is positioned above a semiconductor substrate, in particular a silicon wafer, comprising active devices, e.g., transistors or diodes, composed of appropriate semiconductor regions. The latter is positioned within a trench that extends into the semiconductor substrate.

Current DRAMs using stack capacitors either use metals or doped polycrystalline silicon as the capacitor electrode material. However, polycrystalline silicon has a low conductivity, which leads to a charge depletion layer in the vicinity of the capacitor dielectric layer separating a first and a second capacitor electrode of the stack capacitor. Thus, the effective dielectric thickness increases leading to a decrease of the capacitance value of the storage capacitor. Furthermore, doping within high aspect ratio structures (e.g., doping of a first electrode comprising polycrystalline silicon within an opening) requires several process steps that leads to an increase of production costs. Metals as materials for the capacitor electrodes are difficult to deposit conformally and etching is difficult, so that complex capacitor structures are required to provide a sufficient capacitance value for the storage capacitor.

### SUMMARY

In one embodiment, the invention provides a random access memory, a DRAM stack capacitor and a fabrication method thereof. The DRAM stack capacitor is formed with a first capacitor electrode comprising a conductive carbon layer, a capacitor dielectric layer and a second capacitor electrode.

### BRIEF DESCRIPTION OF THE DRAWINGS

The accompanying drawings are included to provide a further understanding of the present invention and are incorporated in and constitute a part of this specification. The drawings illustrate the embodiments of the present invention and together with the description serve to explain the principles of the invention. Other embodiments of the present invention and many of the intended advantages of the present invention will be readily appreciated as they become better understood by reference to the following detailed description. The elements of the drawings are not necessarily to scale relative to each other. Like reference numerals designate corresponding similar parts.

FIG. 1 (a)-(e) are illustrations of cross-sectional views of one exemplary embodiment of a DRAM stack capacitor during subsequent process steps according to the invention.

### DETAILED DESCRIPTION

In the following Detailed Description, reference is made to the accompanying drawings, which form a part hereof, and in which is shown by way of illustration specific embodiments in which the invention may be practiced. In this regard, directional terminology, such as “top,” “bottom,” “front,” “back,” “leading,” “trailing,” etc., is used with reference to the orientation of the Figure(s) being described. Because components of embodiments of the present invention can be positioned in a number of different orientations, the directional terminology is used for purposes of illustration and is in no way limiting. It is to be understood that other embodiments may be utilized and structural or logical changes may be made without departing from the scope of the present invention. The following detailed description, therefore, is not to be taken in a limiting sense, and the scope of the present invention is defined by the appended claims.

In one embodiment, the present invention provides a DRAM stack capacitor having a first capacitor electrode provided over a conductive region, the conductive region being electrically connected to a transfer device of a memory cell within a semiconductor substrate and the first capacitor electrode having a conductive carbon layer, a capacitor dielectric layer provided over the first capacitor electrode, a second capacitor electrode provided over the capacitor dielectric layer.

The conductive region may also function as a barrier diffusion region, e.g., when contacting a contact plug in order to prevent material diffusion between the contact plug and the first electrode. Furthermore, the conductive region may also prevent oxidation of the plug and it also has to remain conductive after further process steps. The conductive region may be made of TiN, TaN, TaSiN or a combination thereof. However alternative materials or material combinations suited to act as a barrier diffusion region may also be applied. The conductive region may also contact a semiconductor region of the transfer device, e.g., active silicon. In this case, the conductive region may be made of TiSiₓ, CoSiₓ, NiSiₓ or a doped semiconductor material like doped silicon. The capacitor dielectric preferably comprises a high-k material to achieve large capacitance values when using thin dielectrics. As a high-k material metal oxides like Al₂O₃, Ta₂O₅ or TiO₂, ferroelectric materials, BST (BaₓSr₁₋ₓ)TiO₂, SrTiO₃, PZT Pb(Zrₓ, Ti₁₋ₓ)O₃ or SBT SrBi₂Ta₂O₉ may be used, for example.

The transfer device is preferably formed as a MOSFET. However, other types of devices suited to access the storage capacitor may also be used as the transfer device.

The first capacitor electrode formed as a carbon layer preferably comprises a conductivity in the range of 0.2 to 2 mΩcm. This allows the charge depletion layer in the vicinity of the capacitor dielectric layer to be kept small compared to the thickness of the capacitor dielectric layer in order to keep the overall effective thickness of the capacitor dielectric as small as possible. A carbon layer having a conductivity of approximately 1 mΩcm allows the thickness of the depletion layer to be reduced to below 0.5 nm, for example. The carbon layer is especially suited as a first capacitor electrode of a capacitor having a high aspect ratio geometry, e.g., a capacitor having sidewall electrodes, as the deposition process of carbon is conformal to aspect ratios in excess of 50. Furthermore, the carbon layer can be easily etched, e.g., using an oxygen or hydrogen plasma.

It is preferable that the first electrode has a crown shape geometry with sidewalls comprising an inner surface and an outer surface thereof. Such an electrode geometry allows for high capacitance values with regard to a constant chip area using a high aspect ratio structure, i.e., high sidewalls compared to a distance of the sidewalls. Such a high aspect ratio electrode can be realized when using the carbon layer as the first capacitance electrode.

The sidewalls preferably have an average thickness in the range of 5 to 20 nm. The thickness of the sidewalls usually slightly varies from the top of the sidewall down to the bottom, i.e., to the conductive region, due to the deposition process. Therefore, the average thickness considers such variations. For a stack capacitor with an outer diameter of the first capacitor electrode made of carbon of 100 nm, an inner diameter of the first capacitor electrode of 50 nm, a height of 2 μm, a capacitor dielectric layer having a thickness of 3 nm and a dielectric constant, i.e., relative dielectric permittivity, of εᵣ=10 (e.g., Al₂O₃) and a second capacitor dielectric made of carbon a capacitance value in the range of 30 fF is achieved. Such a value is suitable for DRAM storage capacitors.

In one embodiment, it is preferable that at least the outer surface of the first electrode is patterned in order to increase an effective surface area thereof. The pattern may be of irregular shape, e.g., roughened surface, or of regular shape, e.g., corrugated sidewalls. Such an increase of the effective sidewall surface area leads to an increase of the capacitance value compared to a smooth surface area.

In a preferred embodiment the first capacitor electrode, the capacitor dielectric layer and the second capacitor electrode form a planar capacitor.

It is preferable that the second electrode comprises a conductive carbon layer. This allows to achieve capacitor structures having large aspect ratios.

In another preferred embodiment, the second capacitor electrode comprises a metal layer. The metal layer may be formed of one of the materials Pt, Ir, Ru, Pd, for instance using a suitable deposition method like CVD (Chemical Vapor Deposition), PVD (Physical vapor Deposition) or Reactive Sputtering. However, the material selection is not limited to the above metals and may comprise further metals. Furthermore, the second capacitor layer may also comprise metal oxides like IrO₂ or RuO₂, for example.

According to the invention a method is described for fabricating a DRAM stack capacitor including providing a semiconductor substrate having at least a conductive region on a surface, whereby the conductive region is connected to a transfer device of a DRAM memory cell within the semiconductor substrate. A sacrificial layer is formed over the surface, patterning the sacrificial dielectric layer to provide an opening therein above the conductive region, forming a conductive carbon layer covering the conductive region and sidewalls within the openings and a surface of the sacrificial layer, recessing the conductive carbon layer up to the surface of the sacrificial layer to provide a first capacitor electrode within the opening, removing the sacrificial layer, forming a capacitor dielectric layer over the first capacitor electrode and forming a second capacitor electrode over said capacitor dielectric layer.

The material of the sacrificial dielectric layer is chosen inter alia with respect to its etch properties as well as its etch selectivity to the conductive region and the neighboring surface area of the semiconductor substrate not covered by the conductive region. The neighboring surface area may also comprise an etch stop layer to improve the etch selectivity when removing the sacrificial layer. The sacrificial dielectric layer may be a SiO₂ layer and the etch stop layer may be a Si₃N₄ layer, for example. However, many other materials are suited to provide an appropriate etch selectivity and etch properties with regard to the sacrificial dielectric layer. When using SiO₂ as the sacrificial dielectric layer fluoric acid may be used as a etch solution. Patterning said sacrificial dielectric layer is usually carried out as a transfer of a lithographically defined resist pattern to the sacrificial dielectric layer by an etch step. The resist pattern is usually achieved by resist deposition, appropriate radiation exposure (e.g., DUV light or electron beam) through a mask onto said resist and development of the resist. The sacrificial dielectric layer may also not be removed during subsequent process steps in case it may serve as e.g., an ILD (Inter Layer Dielectric).

It should be noted that the semiconductor substrate usually constitutes of a pre-processed silicon wafer that may already comprise e.g., metal layers and ILD depending on the process integration of the storage capacitor. The surface of the semiconductor substrate thus relates to the surface in the pre-processed state.

The carbon layer is preferably formed at temperatures in the range of 500° C. to 1000° C. Further information pertaining deposition of a conductive carbon layer can be found in DE 103 45 393 A1. After formation of the carbon layer also surface areas other than within said openings are covered by the carbon layer. The carbon layer is removed from these surface areas by a recess step, e.g., by an oxygen or hydrogen plasma, to expose the sacrificial dielectric layer. This step also opens up voids within the carbon layer inside the opening in case such voids are formed when processing the carbon layer.

The sacrificial dielectric layer is preferably removed using an etch process depending on the dielectric material, e.g. fluoric acid when using SiO₂ as the sacrificial dielectric layer. The capacitor dielectric layer formed of a high-k material, e.g., a metal oxide like Al₂O₃, Ta₂O₅ or TiO₂, ferroelectric materials, BST (BaₓSr₁₋ₓ)TiO₂, SrTiO₃, PZT Pb(Zrₓ, Ti₁₋ₓ)O₃ or SBT SrBi₂Ta₂O₉ may be fabricated using an appropriate deposition method depending on the choice of material, e.g., MOCVD.

In one embodiment the second capacitor electrode is formed as a conductive carbon layer.

In an alternative embodiment the second capacitor electrode is formed as a metal layer, e.g., by depositing one or more of the materials Pt, Ir, Ru, Pd using a suitable deposition method like CVD (Chemical Vapor Deposition), PVD (Physical vapor Deposition) or Reactive Sputtering. However, the material selection is not limited to the above metals and the metal layer may also comprise metal oxides like IrO₂ or RuO₂, for example.

The second capacitor electrode as well as the capacitor dielectric layer may be covering the DRAMs cell area to provide a single capacitor dielectric layer and a single second capacitor electrode for multiple memory cells.

However, these components of the capacitor may also be structured to provide a single capacitor dielectric layer and a single second capacitor electrode for each memory cell.

It is preferable that the opening is formed by a pulsed etch process to provide patterned sidewalls thereby increasing the effective area. The pulsed etch process may be a dry etch process using variable etch gas supply into the chamber to create the pattern.

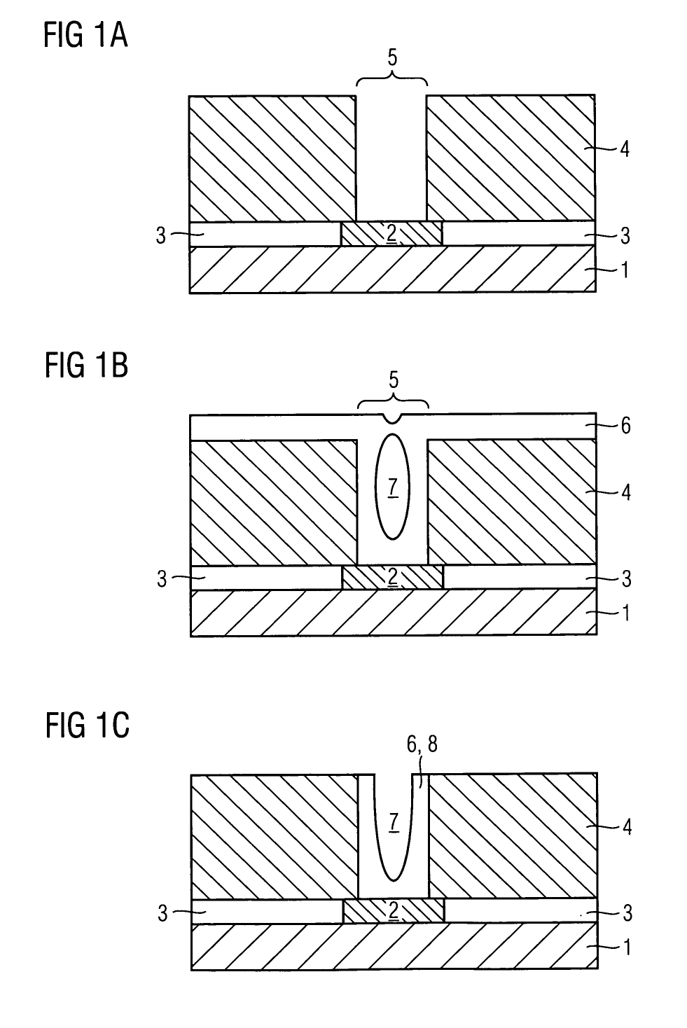

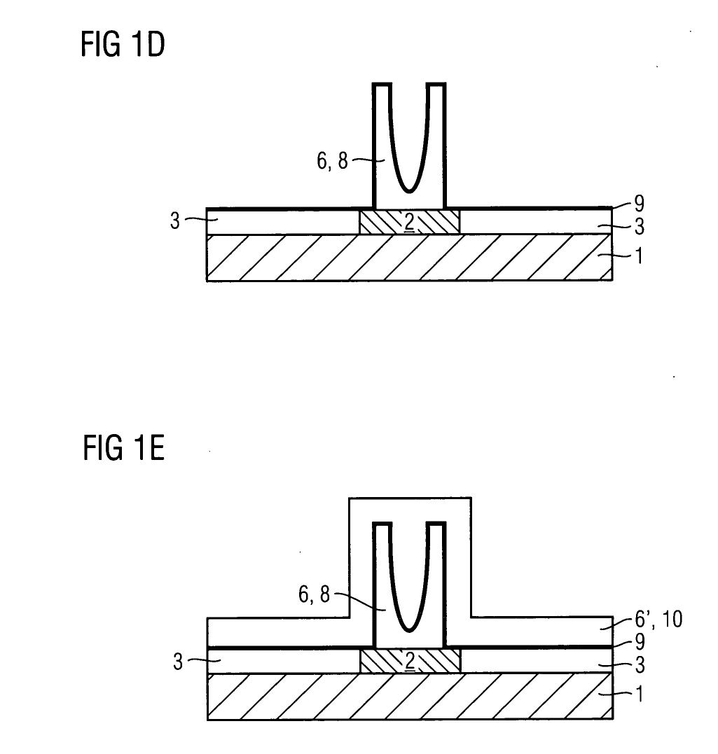

FIG. 1(a) gives an illustration of a cross-sectional view at the beginning of the DRAM stack capacitor fabrication process according to the invention. A pre-processed semiconductor substrate 1 is provided. The pre-processed semiconductor substrate 1 usually is a silicon wafer including active devices, e.g., transistors, within the silicon and it may also comprise e.g., metal layers, ILDs and plugs to contact the active devices. The pre-processed state of the semiconductor substrate 1 strongly depends on the location and the process integration of the storage capacitor. The surface of the pre-processed semiconductor substrate 1 comprises a conductive region 2. The conductive region 2 is in electrical contact to a transfer device of a DRAM memory cell (not shown, hidden in the semiconductor substrate 1). The surface areas of the pre-processed semiconductor substrate 1 other than the conductive region 2 are covered by an etch stop layer 3 providing an etch selectivity with regard to a sacrificial dielectric layer 4 over the pre-processed semiconductor substrate 4. The etch stop layer 3 may also be omitted in case the surface of the pre-processed semiconductor substrate 1 naturally provides an etch selectivity with regard to the sacrificial dielectric layer 4. An opening 5 within the sacrificial dielectric layer 4 exposes at least part of the conductive region 2.

In the schematic cross-sectional view of FIG. 1(b) a conductive carbon layer 6 covers the surface and sidewalls of the sacrificial dielectric layer 4 as well as the conductive region 2 at the bottom of the opening 5. Due to the deposition process of said conductive carbon layer 6 a void 7 is formed within the opening 5.

FIG. 1(c) is a further schematic cross-sectional view during the fabrication process of the DRAM stack capacitor. In order to form a first capacitor electrode 8 out of the conductive carbon layer 6 (see FIG. 1(b)), the conductive carbon layer 6 is recessed by an etch process to open the void 7 within the opening 5 and to remove the conductive carbon layer 6 from the surface of the sacrificial dielectric layer 4.

FIG. 1(d) illustrates an illustrative cross-sectional view after subsequent process based on the process state in FIG. 1(c). After the recess process of the conductive carbon layer illustrated in FIG. 1(c) the sacrificial dielectric layer 4 is removed by an appropriate etch process leaving behind the first capacitor electrode 8 made of the conductive carbon layer 6 in the shape of a crown geometry. The first capacitor electrode 8 is covered by a capacitor dielectric layer 9, i.e., a high-k dielectric. The capacitor dielectric layer 9 fully covers exposed surface areas of the first capacitor electrode 6, i.e., inner and outer sidewalls, as well as the surface of the surrounding etch stop layer 3. The capacitor dielectric layer 9 may be a formed as a single layer covering all memory cells of the DRAM.

In the schematic cross-sectional view of FIG. 1(e) illustrating a subsequent process state with regard to FIG. 1(d) a further conductive carbon layer 6′ is covering the capacitor dielectric electrode to form a second capacitor electrode 10. Outer and inner sidewalls of the first capacitor electrode 8 contribute to the capacitance value of the crown shape DRAM stack capacitor. Similar to the capacitance dielectric layer 9 the second capacitor electrode 10 may also be a formed as a single layer covering all memory cells of the DRAM.

Although specific embodiments have been illustrated and described herein, it will be appreciated by those of ordinary skill in the art that a variety of alternate and/or equivalent implementations may be substituted for the specific embodiments shown and described without departing from the scope of the present invention. This application is intended to cover any adaptations or variations of the specific embodiments discussed herein. Therefore, it is intended that this invention be limited only by the claims and the equivalents thereof.

What is claimed is:

1. A DRAM stack capacitor comprising:
a first capacitor electrode provided over a conductive region, the conductive region being electrically connected to a transfer device of a memory cell within a semiconductor substrate, the first capacitor electrode comprising a conductive carbon layer;
a capacitor dielectric layer provided over the first capacitor electrode; and
a second capacitor electrode provided over the capacitor dielectric layer.

2. The DRAM stack capacitor of claim 1, comprising wherein the first capacitor electrode has a conductivity in the range of 0.2 to 2 mΩcm.

3. The DRAM stack capacitor of claim 2, wherein the first capacitor electrode is of a crown shape geometry with sidewalls comprising an inner surface and an outer surface.

4. The DRAM stack capacitor of claim 3, wherein the sidewalls have an average thickness in the range of 5 to 20 nm.

5. The DRAM stack capacitor of claim 4, wherein at least the outer surface of the first capacitor electrode is patterned in order to increase an effective surface area.

6. The DRAM stack capacitor of claim 2, wherein the first capacitor electrode, the capacitor dielectric layer and the second capacitor electrode form a planar capacitor.

7. The DRAM stack capacitor of claim 1, wherein the second capacitor electrode comprises a further conductive carbon layer.

8. The DRAM stack capacitor of claim 1, wherein the second capacitor electrode comprises a metal layer.

9. A method for fabricating a DRAM stack capacitor comprising:
providing a semiconductor substrate comprising at least a conductive region on a surface thereof, whereas the conductive region is connected to a transfer device of a DRAM memory cell within the semiconductor substrate;
forming a sacrificial dielectric layer over the surface;
patterning the sacrificial dielectric layer to provide an opening therein above the conductive region;
forming a conductive carbon layer covering the conductive region and sidewalls within the opening and a surface of the sacrificial dielectric layer;
recessing the conductive carbon layer up to the surface of the sacrificial dielectric layer to provide a first capacitor electrode within the opening;
removing the sacrificial dielectric layer;
forming a capacitor dielectric layer over the first capacitor electrode; and
forming a second capacitor electrode over the capacitor dielectric layer.

10. The method of claim 9, wherein the second capacitor electrode is formed as a further conductive carbon layer.

11. The method of claim 9, wherein the second capacitor electrode is formed as a metal layer.

12. The method of claim 9, wherein the opening is formed by a pulsed etch process to provide patterned sidewalls to increase an effective area.

13. A random access memory having a stack capacitor comprising:
a semiconductor substrate;
a memory cell having a transfer device, formed within the semiconductor substrate;
a first capacitor electrode provided over a conductive region, the conductive region being electrically connected to the transfer device, the first capacitor electrode comprising a conductive carbon layer;
a capacitor dielectric layer provided over the first capacitor electrode; and
a second capacitor electrode provided over the capacitor dielectric layer.

14. The memory of claim 13, comprising wherein the first capacitor electrode has a conductivity in the range of 0.2 to 2 mΩcm.

15. The memory of claim 14, wherein the first capacitor electrode is of a crown shape geometry with sidewalls comprising an inner surface and an outer surface.

16. The memory of claim 14, wherein the sidewalls have an average thickness in the range of 5 to 20 nm.

17. The memory of claim 15, wherein at least the outer surface of the first capacitor electrode is patterned in order to increase an effective surface area.

18. The memory of claim 14, wherein the first capacitor electrode, the capacitor dielectric layer and the second capacitor electrode form a planar capacitor.

19. The memory of claim 13, wherein the second capacitor electrode comprises a further conductive carbon layer.

20. The memory of claim 13, wherein the second capacitor electrode comprises a metal layer.

21. The memory of claim 20, wherein the memory cell is a dynamic random access memory cell.

22. A DRAM stack capacitor comprising:
first means for providing a capacitor electrode, provided over a conductive region, the conductive region being electrically connected to a transfer device of a memory cell within a semiconductor substrate, the first means comprising a conductive carbon layer;
a capacitor dielectric layer provided over the first means; and
second means for providing a capacitor electrode, provided over the capacitor dielectric layer.
